(19) United States
(12) Patent Application Publication
(10) Pub. No.: US 2006/0118787 A1
(43) Pub. Date: Jun. 8, 2006

(54) Electronic device with electrostatic discharge protection

(75) Inventors: Yi-Hsing Lee, Keelung City (TW); Chu-Jung Shih, Taipei (TW); Jr-Hong Chen, Hsinchu-Hsien (TW)

Correspondence Address: LIU & LIU, 444 S. FLOWER STREET, SUITE 1750, LOS ANGELES, CA, 90071, US

(73) Assignee: Toppoly Optoelectronics Corp.

(21) Appl. No.: 11/003,215

(22) Filed: Dec. 2, 2004

(51) Int. Cl. H01L 29/10

(52) U.S. Cl. 257/66

(57) ABSTRACT

Electronic devices with electrostatic discharge protection are provided. The electronic devices can comprise an array substrate with electrostatic discharge (ESD) protection, having a substrate, a plurality of conductive lines overlying the substrate along a first direction and at least one conductive segment overlying the substrate between every two conductive lines, wherein each conductive segment is electrically isolated from the conductive lines.

### BACKGROUND

The present invention relates to an electronic device, and more particularly to an electronic device having an array substrate with electrostatic discharge (ESD) protection.

Electrostatic discharge (ESD) damage is a well known phenomenon affecting the fabrication of thin film transistor (TFT) arrays. ESD primarily occurs because TFTs are formed on an insulating substrate, such as glass, and the source and drain electrodes, formed of a conducting material, may charge to very high voltages. Additionally, because peripheral circuits to which the TFT array is to be connected are generally not formed on the same substrate as the TFT array, the gate and source lines must extend sufficiently from the TFT array to allow connections of the peripheral circuits to the TFT array via wire bonding pads. Any static charge picked up by the gate and source lines is transferred to the gate and source electrodes of the TFTs as well as to the intersecting nodes of the gate and source lines where the static charge is held. If the static charge reaches a high enough level, the dielectric gate insulating layer between the gate and source electrodes may break down. Even if this break down can be avoided, the voltage differential between the gate and source electrodes or gate and drain electrodes caused by the held static charge may cause the threshold voltage of the TFT to shift in either a positive or negative direction.

Recently, attention has focused on the problems resulting from ESD damage particularly in active matrix flat panel displays, such as LCDs. It is now believed that ESD damage is also caused by equipment related problems during fabrication, handling and testing of these types of devices. The trends to use higher throughput equipment with higher speed substrate handling as well as to downscale during the fabrication process to reduce metal line width and reduce parasitic capacitance in the TFTs has resulted in reduced ESD immunity.

Hence, there is a need for a better TFT array structure with ESD protection for forming electronic devices with ESD protection.

### SUMMARY

In accordance with various embodiments, there is an array substrate with electrostatic discharge (ESD) protection. The array substrate comprises a substrate, a plurality of conductive segments overlying the substrate, wherein at least one of the plurality of conductive segments is disposed between every two conductive lines of the plurality of conductive lines, and wherein each conductive segment is electrically isolated from the conductive lines.

In accordance with various embodiments, there is a display device with electrostatic discharge (ESD) protection. The display device comprises a display panel, and a controller coupled to and driving the display panel to render an image in accordance with an input. The display panel comprises a substrate, a plurality of conductive lines overlying the substrate along a first direction, and a plurality of conductive segments overlying the substrate, wherein at least one of the plurality of conductive segments is disposed between every two conductive lines of the plurality of conductive lines, and wherein each conductive segment is electrically isolated from the conductive lines.

In accordance with various embodiments, there is a method for fabricating an array substrate with electrostatic discharge (ESD) protection. The method comprises the steps of providing a substrate and forming a plurality of gate lines connected by a first conductive line over the substrate. An interlayer dielectric layer is then formed overlying the gate lines and the first conductive line and a plurality of contact holes are then formed in the interlayer dielectric layer overlying the first conductive layer, wherein the contact holes expose portions of the underlying first conductive line between every two gate lines. Next, a conductive layer is formed over the substrate and in the contact holes. The conductive layer and the first conductive line underlying the contact holes are then defined to form a plurality of data lines overlying the gate lines and at least one conducive segment over the substrate between every two the gate lines.

It is to be understood that both the foregoing general description and the following detailed description are exemplary and explanatory only and are not restrictive of the invention, as claimed.

The accompanying drawings, which are incorporated in and constitute a part of this specification, illustrate several embodiments of the invention and together with the description, serve to explain the principles of the invention.

### BRIEF DESCRIPTION OF THE DRAWINGS

Embodiments of the present invention can be more fully understood by reading the subsequent detailed description and examples with references made to the accompanying drawings, wherein:

FIG. 1 is schematic top view of an array substrate with electrostatic discharge (ESD) protection of an embodiment of the invention;

FIGS. 2a-2d are cross sectional views along line A-A′ of FIG. 1 illustrating a method for fabricating the array substrate with electrostatic discharge (ESD) protection according to an embodiment of the invention;

FIGS. 3a-3d are cross sectional views along line B-B′ of FIG. 1, illustrating a method for fabricating a thin film transistor (TFT) on the array substrate according to an embodiment of the invention;

FIG. 4 is a schematic view illustrating a display device of an embodiment of the invention, incorporating a controller; and

FIG. 5 is a schematic diagram illustrating an electronic device incorporating the display device of an embodiment of the invention.

### DESCRIPTION

Reference will now be made in detail to exemplary embodiments of the invention, examples of which are illustrated in the accompanying drawings. It should be noted that the drawings are schematic and relative dimensions and proportions of parts of the cross sections and circuit layout have been exaggerated or reduced in size for the sake of clarity. The same reference symbols are generally used to refer to corresponding or similar features in different embodiments. In addition, expressions such as “overlying the substrate”, “above the layer”, or “on the film” simply denote a relative positional relationship with respect to the surface of the base layer in this specification, regardless of the existence of intermediate layers. Accordingly, these expressions may indicate not only the direct contact of layers, but also, a non-contact state of one or more laminated layers.

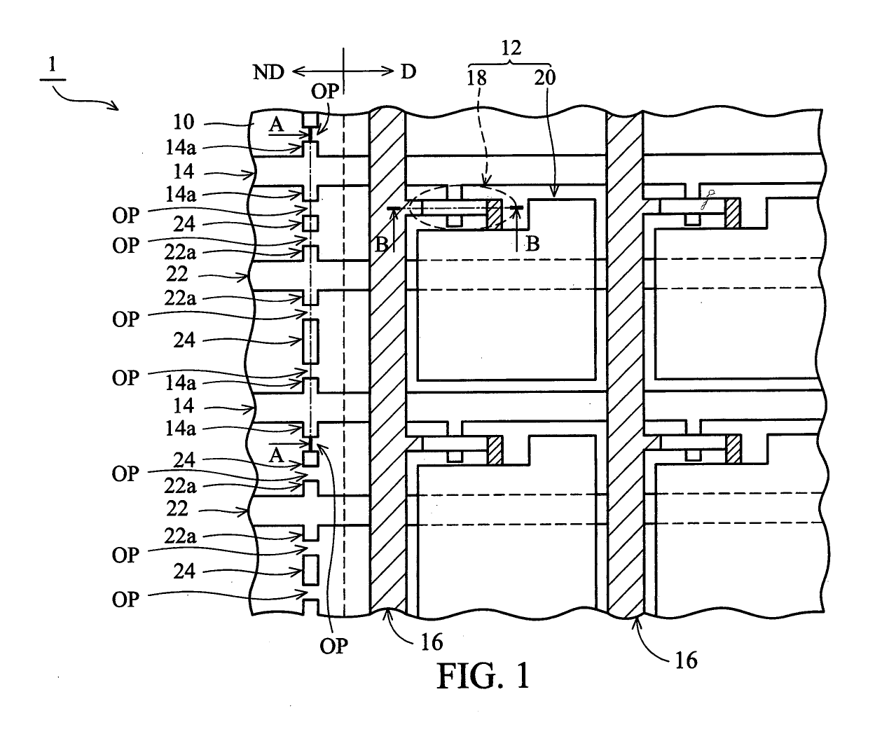

In FIG. 1, a schematic top view of an array substrate 1 with electrostatic discharge (ESD) protection according to an embodiment of the invention is partially illustrated. Here, array substrate 1 is shown as an active matrix array substrate for fabrication of a liquid crystal display (LCD) device or an electroluminescent (EL) display device but is not restricted thereto.

Array substrate 1 can include a plurality of pixel regions 12 formed over a substrate 10, defined by a plurality of gate lines 14 overlying substrate 10 in a row direction and a plurality of data lines 16 overlying substrate 10 in a column direction. Here, pixel regions 12 can be formed within a display area D and each pixel region 12 can comprise a thin film transistor (TFT) region 18 electrically connected to gate line 14 and a display region 20 electrically connected thereto. Normally, but not necessarily, a common electrode 22 can be formed between two adjacent gate lines 14 along the row direction and underlying each display region 20. The portion of the common electrode 22 underlying the pixel region 12 can function as a bottom electrode for forming a storage capacitor (not shown).

Moreover, a conductive segment 24 can be formed over the substrate 10 between two adjacent gate lines 14 within a s non-display area ND and isolated by the openings OP formed therebetween. The conductive segment 24 can be also formed over the substrate 10 between the common electrode 22 and the adjacent gate line 14 thereof, substantially arranged in a line. In addition, each gate line 14 and each common electrode 22 in the non-display area ND may include a pair of conductive fins 14a and 22a, respectively. The pair of conductive fins 14a can include a first fin that extends from a first side of each gate line 14 and a second fin that extends from a second side of each gate line 14, as shown in FIG. 1. Similarly, the pair of conductive fins 22a can include a first fin that extends from a first side of common electrode 22 and a second fin that extends from a second side of common electrode 22, as shown in FIG. 1. The conductive fins 14a, 22a, and the conductive segments 24 therebetween can be substantially arranged in a line and isolated by the openings OP formed therebetween. The conductive fins 14a, 22a, and the conductive segments 24 as shown in FIG. 1 provide electrostatic discharge protection during fabrication of the pixel regions 12 and the TFT regions 18 and ensure functionality of the device in the TFT regions 18 and the display region 20.

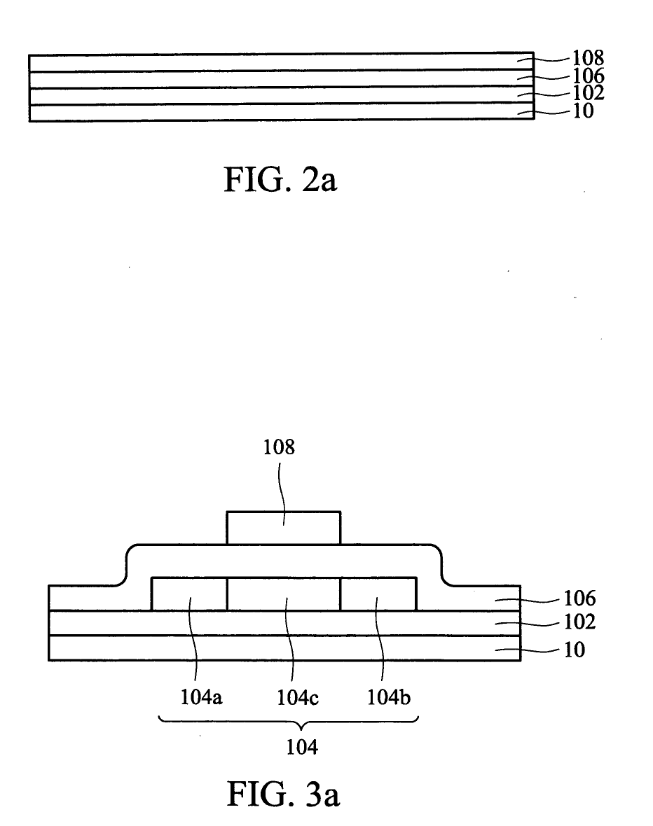

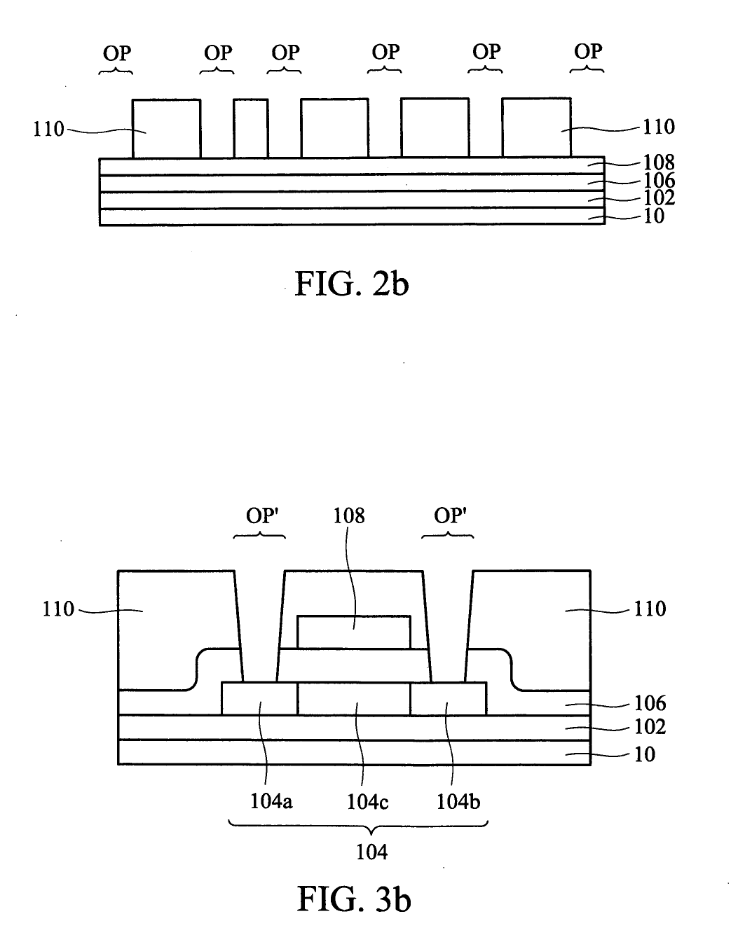

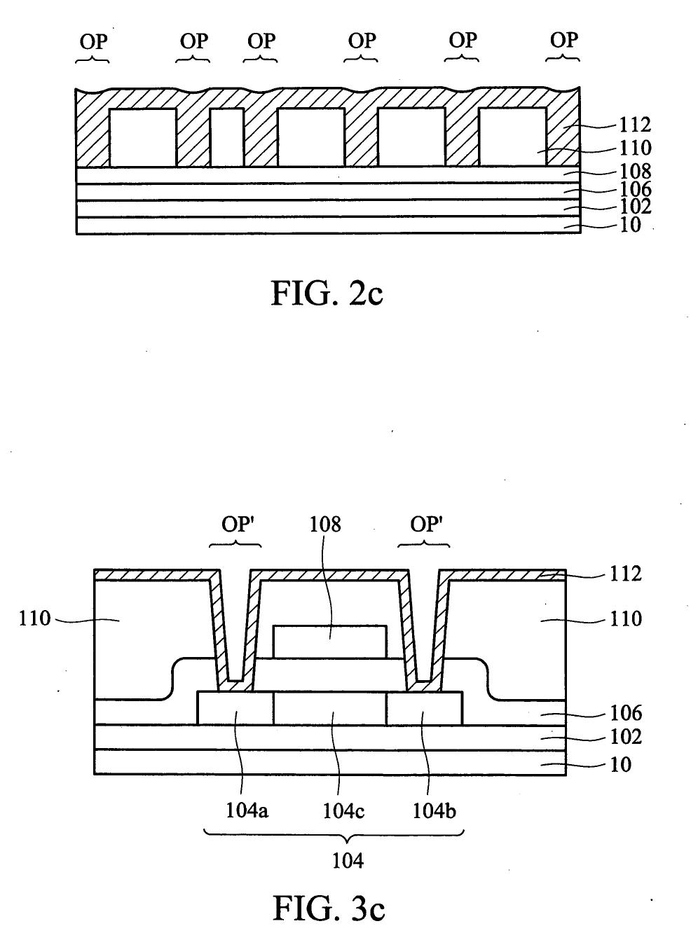

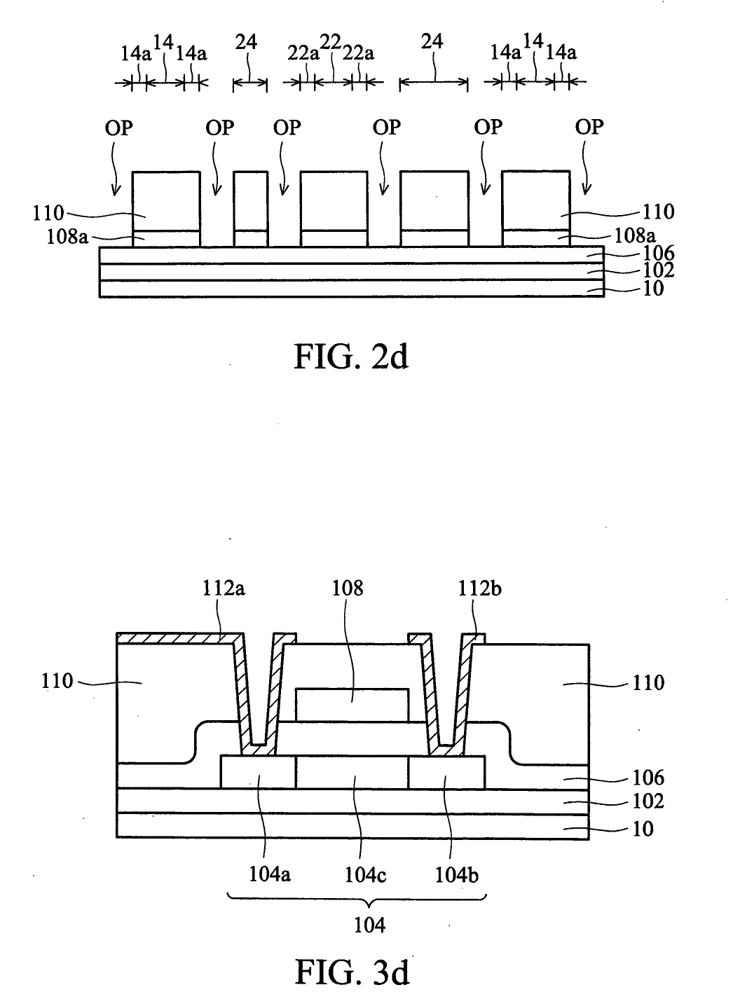

Fabrication of conductive fins 14a, 22a, and conductive segments 24 in FIG. 1 which can provide electrostatic discharge protection are further illustrated in the cross sections FIG. 2a-2d taken along line A-A′ of FIG. 1. In FIGS. 3a-3d, cross sections along line B-B′ of FIG. 1 are illustrated, and show fabrication process for a thin film transistor in TFT region 18.

In FIGS. 2a and 3a, a transparent substrate, for example substrate 10, is provided. A buffer layer 102, for example a layer of silicon nitride, silicon oxide or combinations thereof, can then be formed on substrate 10. Next, an active layer 104 can be formed on buffer layer 102 in TFT region 18 by sequential deposition and patterning of, for example, an amorphous silicon layer or polysilicon layer. A blanket insulating layer 106 can then be formed on substrate 10 and can cover the underlying buffer layer 102 and active layer 104 in TFT region 18. Next, patterned conductive layers 108 can be formed by sequential deposition and patterning a layer of conductive material such as molybdenum (Mo) or aluminum (Al) on substrate 10, thus forming gate lines 14 and common electrodes 22 on the substrate (referring to FIG. 1). Next, an ion implantation (not shown) can be performed to substrate 10 to implant proper dopants into portions of active layer 104, using conductive layers 108 as implant masks. Thus, a source region 104a and a drain region 104b doped with proper dopant can thus be formed in active layer 104 and a channel region is also formed therebetween. In FIG. 3a, conductive layer 108 can function as a gate electrode of a thin film transistor and a thin film transistor is thus fabricated.

In FIG. 2a, conductive layer 108 can function as a conducting line connecting gate line 14 and common electrode 22 (referring to FIG. 1) and can connect thereto during fabrication of a TFT, thus providing additional conductive paths for allowing diffusion of electrostatic charges accumulated during device fabrication. Portions of the conductive line formed by conductive layer 108 can also function as a part of the gate lines and the common electrodes.

In FIGS. 2b and 3b, an interlayer dielectric layer 110 can then be formed on substrate 10 and then patterned to form a plurality of openings OP and contact openings OP′. In FIG. 2b, the openings OP expose a portion of the underlying conductive layer 108. In FIG. 3b, the contact openings OP′ expose a portion of source region 104a and drain region 104b, respectively.

In FIGS. 2c and 3c, the openings OP, source region 104a and drain region 104b can then be covered with a second conductive layer 112. Second conductive layer 112 can conformably cover the contact openings OP′ and fill the openings OP, electrically connecting with source region 104a, drain region 104b and conductive layer 108, respectively. Second conductive layer 112 can be a single conductive layer or a multiple conductive layer such as a Mo—Al—Mo trilayer. In various embodiments, second conductive layer 112 can comprise the same material as that of the underlying conductive layer 108.

In FIGS. 2d and 3d, second conductive layer 112 can then be patterned to form data lines (referring to the data liens 16 shown in FIG. 1), overlying the gate lines and common electrode (referring to the gate lines 14 and the common electrode 22 shown in FIG. 1), and source/drain regions 104a/104b of the TFT. In FIG. 3d, patterned second conductive layers 112a and 112b electrically connecting source region 104a and drain region 104b can thus be formed. Second conductive layer 112a can connect an adjacent data line (not shown) with source region 104a and second conductive layer 112b can connect drain region 104b and a sequentially formed display region (not shown).

During the patterning of second conductive layer 112, second conductive layer 112 in the non-display area ND can be entirely removed and an over-etching may be also performed to ensure that no conductive residue remains on the surface of ILD layer 110 in the non-display area ND. Here, during the described over-etching, portions of conductive line 108 in the openings OP are also removed, thus leaving conductive segments 24 and conductive fins 14a, 22a extending along both sides of the gate lines and common electrodes 22 as shown in FIG. 2d. The goal of ESD protection during TFT device fabrication is thus achieved. Possibility of shorts between two adjacent gate lines or between the common electrode and the adjacent gate line thereof can be eliminated by forming at least two openings OP therebetween.

As shown in FIG. 1, gate lines 14 and common electrodes 22 of the described embodiment can be conducted by a conductive layer (not shown) prior to formation of data lines 16, thus providing additional ESD protection against the electrostatic charges accumulated during fabrication of pixel regions 12. Portions of the conductive layer can be exposed and then cut off during the formation of the data line, thus leaving conductive segments 24 and conductive fins 14a or 22a extending along both sides of the gate lines and common electrodes 22, and a plurality of openings OP can be formed therebetween to prevent shorts. ESD damage prior to pixel formation can be prevented by the method and the structure provided by the described embodiment, thus reducing undesired mura phenomenon caused by ESD damage to the TFT devices in the pixel regions.

Moreover, other conventional ESD protection such as contact pads or shoring bars can be further incorporated with the method and the structure provided by the described embodiment and is not restricted by the embodiment.

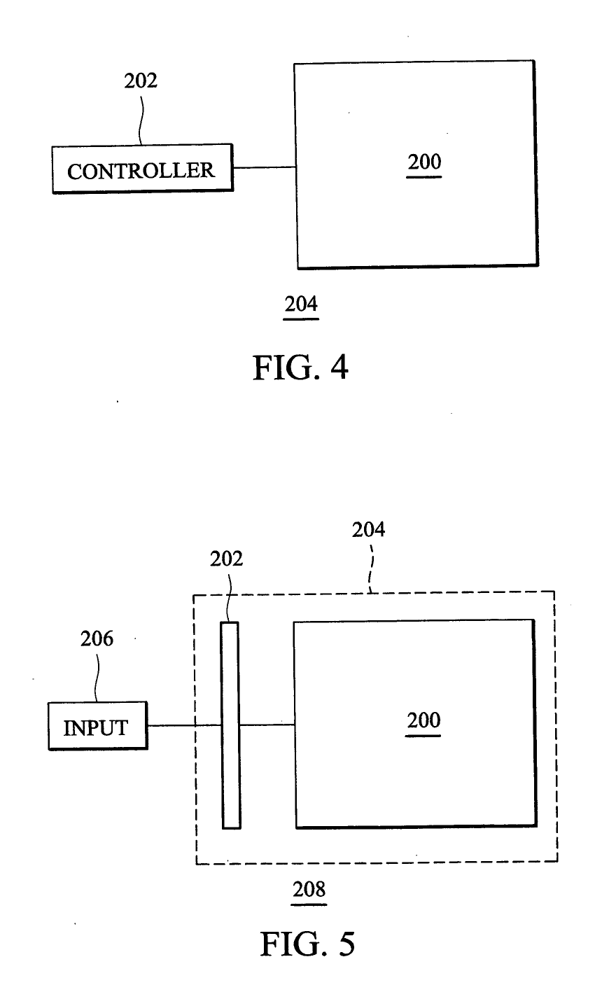

Further, array substrate 1 can be utilized in the fabrication of a display panel 200 such as a LCD panel or an OLED panel and display panel 200 can be coupled to a controller 202, forming a display device 204 as shown in FIG. 4. Moreover, display panel 200 can include an opposing substrate (not shown) disposed opposite to array substrate 1. Controller 202 can comprise source and gate driving circuits (not shown), controlling display panel 200 for operation of display device 204.

FIG. 5 is a schematic diagram illustrating an electronic device incorporating display device 204 shown in FIG. 4. An input device 206 can be coupled to controller 202 of display device 204 shown in FIG. 4 to form an electronic device 208. Input device 206 can include a processor or the like to input data to controller 202 to render an image. In various embodiments, electronic device 208 can be a portable device such as a PDA, notebook computer, tablet computer, cellular phone, or a display monitor device, or a non-portable device such as a desktop computer.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An array substrate with electrostatic discharge (ESD) protection, comprising:
a substrate;
a plurality of conductive lines overlying the substrate along a first direction; and
a plurality of conductive segments overlying the substrate, wherein at least one of the plurality of conductive segments is disposed between every two conductive lines of the plurality of conductive lines, and wherein each conductive segment is electrically isolated from the conductive lines.

2. The array substrate as claimed in claim 1, wherein each of the plurality of conductive lines comprises a pair of conductive fins, wherein a first conductive fin of the pair of conductive fins extends towards a first side and a second conductive fin of the pair of conductive fins extends towards a second side.

3. The array substrate as claimed in claim 2, wherein the plurality of pairs of conductive fins and the plurality of conductive segment are arranged along a second direction distinct from the first direction.

4. The array substrate as claimed in claim 3, wherein the second direction is substantially perpendicular to the first direction.

5. The array substrate as claimed in claim 3, further comprising a plurality of common electrodes overlying the substrate, wherein each of the plurality of common electrodes is disposed between two conductive lines of the plurality of conductive lines, and wherein the common electrode is electrically isolated from the conductive segment.

6. The array substrate as claimed in claim 5, wherein each of the plurality of common electrodes comprises a pair of conductive fins, and wherein a first conductive fin of the pair of conductive fins extends towards a first side and a second conductive fin of the pair of conductive fins extends towards a second side.

7. The array substrate as claimed in claim 6, wherein the pair of conductive fins of each of the plurality of common electrodes, the pair of conductive fins of each of the plurality of conductive lines, and the conductive segment. are substantially arranged in a line.

8. The array substrate as claimed in claim 1, wherein the conductive lines are gate lines connecting to a gate electrode of a thin film transistor disposed on the substrate.

9. A display device with electrostatic discharge (ESD) protection, comprising:
a display panel, comprising:
a substrate;
a plurality of conductive lines overlying the substrate along a first direction; and
a plurality of conductive segments overlying the substrate, wherein at least one of the plurality of conductive segments is disposed between every two conductive lines of the plurality of conductive lines, and wherein each conductive segment is electrically isolated from the conductive lines; and
a controller coupled to and driving the display panel to render an image in accordance with an input.

10. The display device as claimed in claim 9, wherein the display panel is a liquid crystal display (LCD). panel.

11. The display device as claimed in claim 9, wherein the display panel is an electroluminescent display panel comprising an electroluminescent layer.

12. The display device as claimed in claim 11, wherein the electroluminescent layer comprises a polymer material and the electroluminescent display panel is a polymer light emitting diode (PLED) display.

13. The display device as claimed in claim 11, wherein the electroluminescent layer comprises an organic material and the electroluminescent display panel is an organic light emitting diode (OLED) display.

14. A method for fabricating an array substrate with electrostatic discharge (ESD) protection, comprising:
providing a substrate;
forming a plurality of gate lines connected by a conductive line over the substrate;
forming an interlayer dielectric layer overlying the plurality of gate lines and the conductive line;
forming a plurality of contact holes in the interlayer dielectric layer overlying the conductive layer, wherein the plurality of contact holes expose portions of the underlying conductive line between every two gate lines of the plurality of gate lines;
forming a conductive layer over the substrate and in the plurality of contact holes; and
defining the conductive layer and the conductive line underlying the plurality of contact holes to form a plurality of data lines overlying the plurality of gate lines and at least one conductive segment over the substrate between every two gate lines of the plurality of gate lines.

15. The method as claimed in claim 14, wherein during the step of forming the plurality of gate lines, a common electrode is formed over the substrate between every two gate lines of the plurality of gate lines, the common electrode electrically connected to the plurality of gate lines.

16. The method as claimed in claim 14, wherein during the step of forming the plurality of gate lines, a gate electrode of a thin film transistor is formed over the substrate, the gate electrode connected to the plurality of gate lines.

17. The method as claimed in claim 14, wherein during the step of forming the plurality of data lines, a source electrode and a drain electrode of the thin film transistor are formed over the interlayer dielectric layer, the source electrode electrically connected to the plurality of data lines.

18. The method as claimed in claim 14, wherein a definition of the conductive layer is performed by a photolithography procedure and a subsequent dry etching procedure.

19. The method as claimed in claim 18, wherein the dry etching comprises an over-etching procedure.

20. The method as claimed in claim 18, wherein the conductive layer overlying the first conductive line is entirely removed during the definition thereof.
